(19) United States
(12) Patent Application Publication
(10) Pub. No.: US 2026/0033366 A1
(43) Pub. Date: Jan. 29, 2026

(54) APPARATUS WITH VARIED COMMUNICATION PATH MECHANISM AND METHODS FOR MANUFACTURING THE SAME

(71) Applicant: Micron Technology, Inc., Boise, ID (US)

(72) Inventors: Yongsuk Choi, Sugar Hill, GA (US); Raghukiran Sreeramaneni, Frisco, TX (US)

(21) Appl. No.: 19/275,950

(22) Filed: Jul. 21, 2025

Related U.S. Application Data
(60) Provisional application No. 63/676,243, filed on Jul. 26, 2024.

(51) Int. Cl. H01L 23/538; G06F 30/3953; H01L 21/48; H10B 80/00

(52) U.S. Cl. CPC H01L 23/5386; G06F 30/3953; H01L 21/4846; H10B 80/00

(57) ABSTRACT

Methods, apparatuses, and systems related to communicative paths having length-dependent widths are described. Apparatus may have communicative paths that have different widths and/or spacings or pitches to coordinate the signal timing.

### CROSS-REFERENCE TO RELATED APPLICATION(S)

The present application claims priority to U.S. Provisional Patent Application No. 63/676,243, filed Jul. 26, 2024, the disclosure of which is incorporated herein by reference in its entirety.

### TECHNICAL FIELD

The disclosed embodiments relate to devices, and, in particular, to semiconductor devices with varied communication path mechanism and methods for operating the same.

### BACKGROUND

An apparatus (e.g., a processor, a memory system, and/or other electronic apparatus) can include one or more semiconductor circuits configured to store and/or process information. For example, the apparatus can include a memory device, such as a volatile memory device, a non-volatile memory device, or a combination device. Memory devices, such as dynamic random-access memory (DRAM), can utilize electrical energy to store and access data.

With technological advancements in embedded systems and increasing applications, the market is continuously looking for faster, more efficient, and smaller devices. To meet the market demands, the semiconductor devices are being pushed to the limit with various improvements. Improving devices, generally, may include increasing circuit density, increasing operating speeds or otherwise reducing operational latency, increasing reliability, increasing data retention, increasing functionalities, reducing power consumption, or reducing manufacturing costs, among other metrics.

### BRIEF DESCRIPTION OF THE DRAWINGS

FIG. 1 a cross-sectional view of a system-in-package device in accordance with embodiments of the technology.

FIG. 2A is a schematic plan view of a first example apparatus in accordance with embodiments of the technology.

FIG. 2B is a schematic plan view of a second example apparatus in accordance with embodiments of the technology.

FIG. 3 is a flow diagram illustrating an example method of manufacturing an apparatus in accordance with an embodiment of the present technology.

FIG. 4 is a schematic view of a system that includes an apparatus in accordance with an embodiment of the present technology.

### DETAILED DESCRIPTION

As described in greater detail below, the technology disclosed herein relates to an apparatus, such as for electronic systems, semiconductor devices, related methods, etc., for providing varied communication path mechanism. The apparatus can include electronic circuits embedded/formed within or attached to a substrate (e.g., a semiconductor substrate, a Printed Circuit Board (PCB)). The electronic circuits can be electrically coupled to each other through communication paths, such as laterally extending paths or traces, vertically extending vias and connectors, or a combination thereof.

The communication paths can have electrical characteristics, such as resistance and/or susceptibility to capacitance, that influence the signals communicated through the communication paths. For example, the electrical characteristics can introduce delays, skews, noises, and/or other unwanted signal changes or degradations into the communicated signals. Such unwanted effects can further vary based on the circuit layout (e.g., relative locations of the circuits/paths), thereby further increasing the difficulties in enforcing timing requirements. In some instances, delay difference in a group of signal (e.g., static skew) can be related to valid window reduction. Routing congestion and non-symmetric circuit architecture increase the difficulties in controlling/matching delays among signals in the same group. Such difficulties are further increased when the data rate is high, and the data travels longer distances.

Given such challenges, the apparatus can include the varied communication path mechanism for controlling the effects of the electrical characteristics on the communicated signals. In some embodiments, the varied communication path mechanism can include channel dimensions that vary according to the signal travel/flight distances. For example, a lateral path (e.g., a signal trace) can have a width that is based on or related to a distance or a length between corresponding communicating endpoints (e.g., a signal flight distance). Similarly, a vertical path (e.g., a via, a post, a pedestal, and/or the like) can have a thickness that is based on or related to the signal flight distance. In some embodiments, for a given pitch, traces having shorter flight distances can have wider widths than traces having longer flight distances. Accordingly, in maintaining the given pitch, the separation distances can differ according to pitch widths.

By controlling and varying the path width/thickness (e.g., dimension(s) orthogonal to the traversal direction of the signal) according to the flight distance, the varied communication path mechanism can control the electrical characteristics, such as electrical resistance and/or capacitance, to adjust or compensate for the flight distance. Accordingly, the varied path dimensions can provide increased timing margins and reduce related timing errors/delays, such as for groupings of timing-dependent signals.

### Example Environment

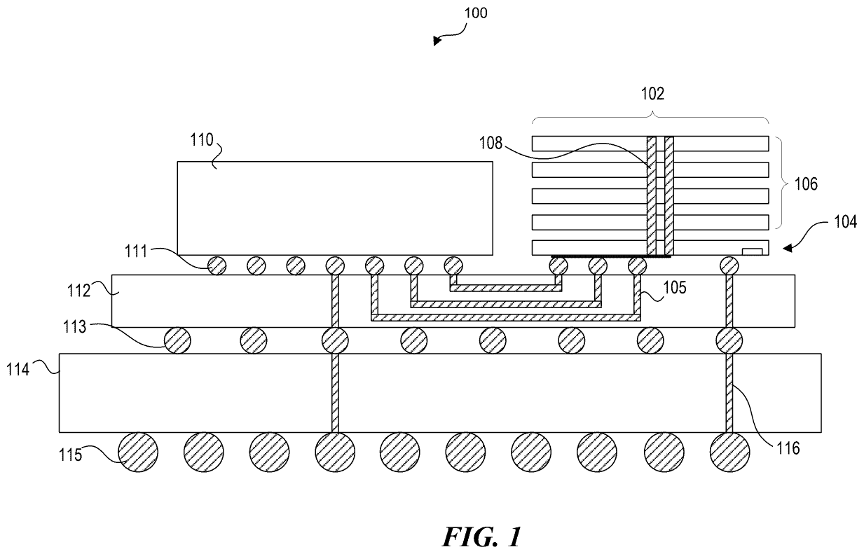

FIG. 1 illustrates a schematic cross-sectional view of a system-in-package (SiP) device 100 (i.e., an example apparatus) in accordance with embodiments of the technology. The SiP 100 can include a memory device 102 and a processor 110 (e.g., a central processing unit (CPU), a graphics processing unit (GPU), or the like), which are packaged together on a package substrate 114 along with an interposer 112. The processor 110 may act as a host device of the SiP 100.

In some embodiments, the memory device 102 may be a high-bandwidth memory (HBM) device that includes an interface die (or logic die) 104 and one or more memory core dies 106 stacked on the interface die 104. The memory core dies 106 can include DRAM devices/dies, NAND devices/dies, and/or other types of memory devices (e.g., static RAM (SRAM)) as main memory configured to store data provided by the processor 110 and to provide access of the stored data to the processor 110. The memory device 102 can further include additional and/or supplementary memory circuits (e.g., SRAM, DRAM, NAND, etc.), located within and/or outside of the core dies 106, configured for internal uses (e.g., remaining inaccessible to the processor 110). The memory device 102 can include one or more through silicon vias (TSVs) 108, which may be used to couple the interface die 104 and the core dies 106.

The interposer 112 (e.g., a silicon interposer) can provide electrical connections between the processor 110, the memory device 102, and/or the package substrate 114. For example, the processor 110 and the memory device 102 may both be coupled to the interposer 112 by a number of internal connectors (e.g., micro-bumps 111). The interposer 112 may include channels 105 (e.g., an interfacing or a connecting circuit) that electrically couple the processor 110 and the memory device 102 through the corresponding micro-bumps 111. While three channels 105 are shown in FIG. 1, greater or fewer numbers of channels 105 may be used. The interposer 112 may be coupled to the package substrate by one or more additional connections (e.g., intermediate bumps 113, such as C4 bumps).

The package substrate 114 can provide an external interface for the SiP 100. The package substrate 114 can include external bumps 115, some of which may be coupled to the processor 110, the memory device 102, or both. The package substrate may further include direct access (DA) bumps coupled through the package substrate 114 and interposer 112 to the interface die 104.

The memory device 102 can include memory in addition to the core dies 106 and/or the targeted memory cells therein. For example, the memory device 102 can include SRAM, persistent memory (e.g., NAND), hybrid memory devices, and/or the like in the interface die 104 and/or (in addition to the targeted memory cells, such as DRAM) in the core dies 106. In some embodiments, the core dies 106 can include multiple different types of memories or hybrid devices as the targeted memory cells. For example, the core dies 106 can include DRAM dies and NAND dies stacked on/over each other.

One or more components of an apparatus, such as a semiconductor and/or an electronic device, can include communication paths having flight-distance-dependent cross-sectional dimensions (e.g., widths or thicknesses). Using the SiP 100 as an example, the memory device 102 (e.g., at the core dies 106 and/or the interface die 104), the interposer 112, the processor 110, and/or the package substrate 114 can include varied communication path mechanism.

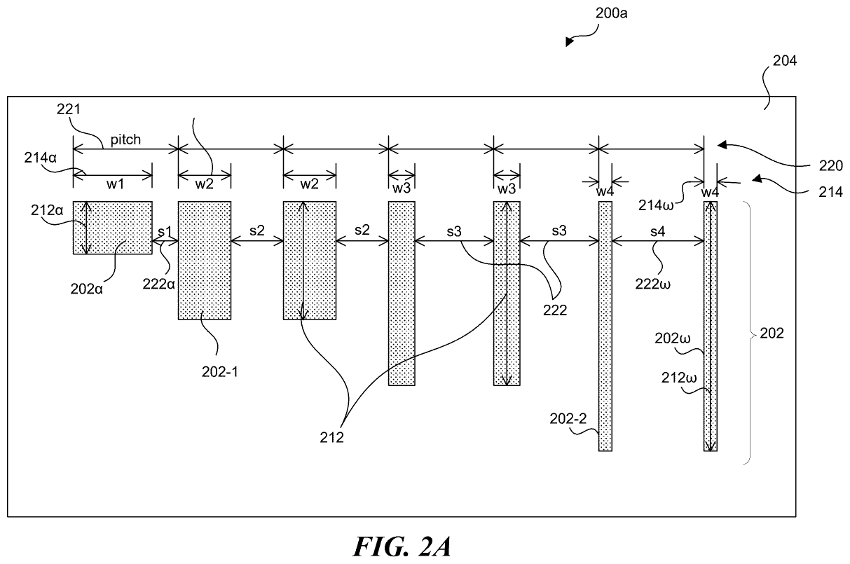

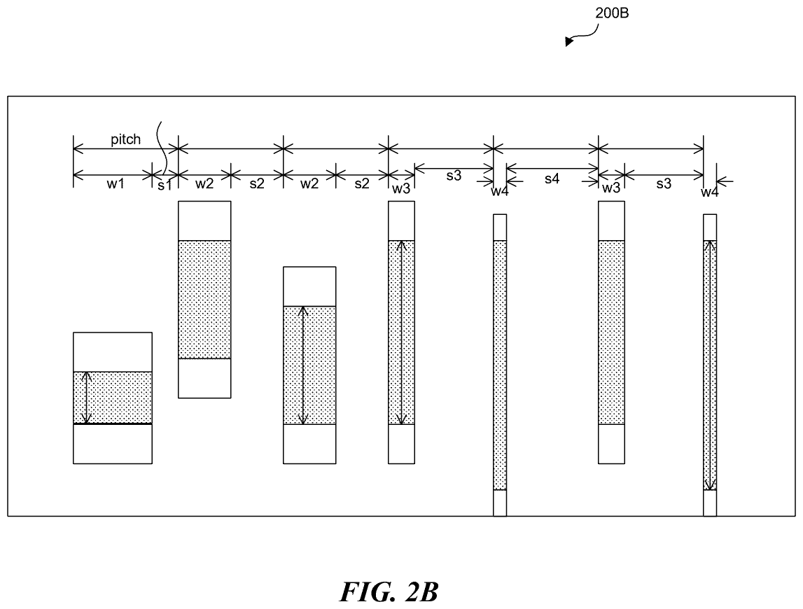

FIG. 2A and FIG. 2B illustrate examples of the varied communication path mechanism. FIG. 2A is a schematic plan view of a first example apparatus 200a (e.g., a semiconductor device, such as a die or a wafer), and FIG. 2B is a schematic plan view of a second example apparatus 200b, both in accordance with embodiments of the technology. Referring to FIG. 2A and FIG. 2B together, the first apparatus 200a and the second apparatus 200b can each include a set of communication paths 202 on a substrate 204, such as semiconductor substrate, a PCB, or the like. The set of communication paths 202 can include conductive structures, such as wires, traces, vias, posts, and/or the like, configured to communicate electrical signals or voltages between endpoints.

In some embodiments, the set of communication paths 202 can be configured to communicate coordinate signals. For example, the set of communication paths 202 can include a subset of traces on a semiconductor device that is used to communicate signals that have related timing restrictions or signals that are temporally coordinated to different endpoints. Examples of such timing dependent signals can include signals that are required to arrive within a relatively small timing window, such as for clock signals, strobes, broadcast signals, parallel signals, and/or the like.

Each path within the set 202 can have a flight distance 212 that corresponds to a distance along a signal path between communicating endpoints. In other words, the flight distance 212 can correspond to a length of the path between the communicating endpoints and the distance that a signal will travel along the corresponding communication path.

Further, each path within the set can have a path dimension 214 measured along a direction orthogonal to the flight distance 212. For example, the path dimension 214 can include a width and/or a thickness of the communication path (e.g., trace).

The path dimension 214 can be associated with the flight distance 212. Accordingly, the paths within the set 202 can have different values for the path dimension 214. Further, for a given path pitch 220 (e.g., spatial arrangement/separation between the set of paths 202) that preserves a constant pitch distance 221 between reference points (e.g., left edge as shown in FIG. 2A), the variable path dimension 214 can further provide variable separation distance 221. The separation distance 221 can correspond to the distance between nearest, facing, or adjacent edges of adjacently located paths within the set 202.

The variations in the path dimension 214 and the corresponding variations in the separation distance 221 within the set of paths 202 can provide different electrical characteristics, such as resistance and/or capacitance, that affect signal propagation. Thus, the path dimension 214 can be controlled to adjust and coordinate the timing of signals communicated across the set of paths 202.

As an illustrative example, the set of paths 202 can connect Through-Silicon Vias (TSVs) to corresponding physical layer (PHY) circuits. Additionally or in different applications, the set of paths 202 can be used to communicate signals that are temporally related to each other, such as synchronous or simultaneously sent/received signals (e.g., clocks, strobes, broadcasts, etc.). The TSVs and the PHY can be asymmetrical across the set of paths 202 such that the paths therein have different flight distances. To account for the asymmetry, the differences in the static skew of the signals, and the corresponding skew/tolerance window to receive the coordinated signals, each path in the set 202 can have the path dimension 214 that is based on the flight distance 212 thereof.

The path dimension 214 can be calculated using or based on the flight distance 212, the separation distance 222, or a combination thereof. In some embodiments, a designing system (e.g., a computer system) can determine or receive a circuit layout, a layout for the set of paths 202, the path pitch 220, or a combination thereof. The designing system can identify a longest flight distance and a shortest flight distance. Using a predetermined or a trained computing model, the designing system can calculate the path dimension 214 for each path in the set 202 according to the one or more of inputs and intermediate computational results described above. For example, the model can compute the resistance and capacitance of the paths for various values of widths and predict the corresponding affect on the communicated signals. The model can be configured to minimize the variations in the communicated signal at a receiving endpoint.

As an illustrative example, the designing system can identify (1) a first reference path 202α having a first reference length 212α (e.g., the longest flight distance) and (2) a second reference path 202ω a second reference length 212ω (e.g., the shortest flight distance) within the set of paths 202. The set of paths 202 can have a given value for the pitch 220 and be configured to communicate signals that have relative timing requirements. As described above, the designing system can compute a first reference width 214α for the first reference path 202α and a second reference width 214ω for the second reference path 202ω. Using the given value for the pitch 220, the varied widths can provide varied separations, such as (1) a first separation distance 222α between facing edges on the first reference path 202α and a first adjacent path 202-1 that is adjacent to the first reference path 202α and (2) a second separation distance 222ω between facing edges on the second reference path 202ω and a second adjacent path 202-2 adjacent to the second reference path 202ω.

For an example embodiment, the set of paths 202 can have flight distances 212 that are between 100 um to 1,000 um (e.g., 300 um, 400 um, etc.). The variations in the flight distances 212 within the set of paths 202 can result in differences in the RC constant and corresponding delays/skews. By varying the path widths according to the distances (e.g., 0.05 um to 0.5 um), the set of paths 202 can provide signals with delays that vary less than 5% for flight distances that differ by 25%, 50%, or more.

For illustrative purposes, the first example shows the set of paths 202 aligned at the top portion of FIG. 2A, having increasing flight distances moving toward the right of FIG. 2, and grouping paths having matching flight distances. However, it is understood that the set of paths can be different as illustrated in FIG. 2B. Based on the locations/requirements of the endpoints, the set of paths 202 can be arranged without an alignment, with limited patterns or without any patterns in the flight distances in the arrangement of the paths, and/or without grouping the paths. Moreover, in some embodiments, the set of paths 202 can have the narrowest width (e.g., the path dimension 214 corresponding to a predetermined minimum, such as a manufacturing limitation or an industry standard value) for the longest flight path. In other embodiments (not shown), the set of paths 202 can have widest width for the longest flight path.

### Example Flow

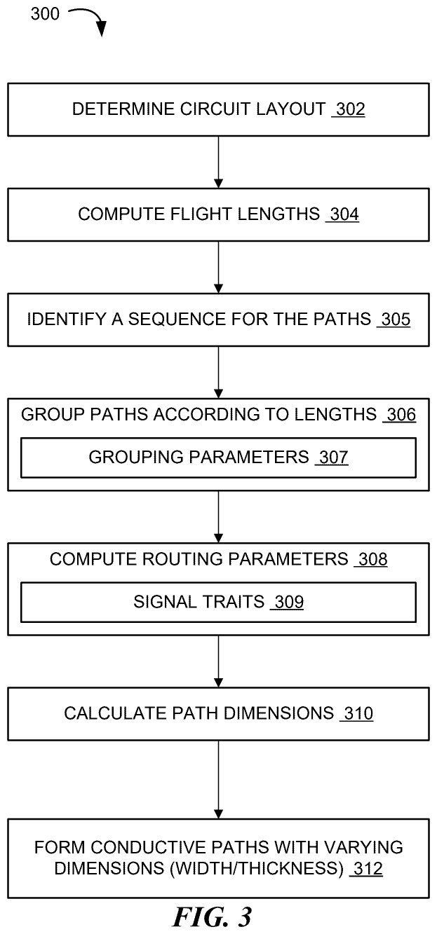

FIG. 3 is a flow diagram illustrating an example method 300 of manufacturing an apparatus (e.g., the SiP 100 of FIG. 1, the apparatus 200a of FIG. 2A, the apparatus 200b of FIG. 2B, etc.) in accordance with an embodiment of the present technology. The method 300 can be for manufacturing the apparatus 200a, the apparatus 200b, the SiP 100, a portion thereof, or a combination thereof.

At block 302, the method 300 can include determining a circuit layout. For example, a computing system can receive a circuit diagram, a netlist, a substrate design, a die design, a layer description or the like from a circuit designer, a customer, or the like. In some embodiments, determining the circuit layout can include selecting the circuit components, computing/generating the placement locations on the die/PCB, or the like according to targeted circuit performance and/or outputs. The resulting circuit layout can include specific locations of circuit components and physical locations of connections including the set of paths 202 of FIG. 2A (e.g., traces). In some embodiments, the circuit layout can provide three-dimensional context for the corresponding or targeted circuit. For example, the circuit layout can identify a vertical location (e.g., bottom die, top die, lower/upper half, position identifier, or the like) for the circuit within a corresponding die stack.

At block 304, the method 300 can include computing flight lengths (e.g., the flight distance 212 of FIG. 2A) for the conductive paths. A computing system can review the circuit layout and follow the communication paths between communicating components according to signal travel. Based on the followed signal travel, the computing system can measure the corresponding distance. The computing system can log the resulting distance as the flight distance 212 for the corresponding communication path.

At block 305, the method 300 can include identifying a sequence for the paths according to the flight lengths. For example, the computing system can identify the sequence between a shortest path and a longest path within the set. In some embodiments, the computing system can generate an ordered list or sort the paths or corresponding representations thereof for the set.

At block 306, the method 300 can include grouping the conductive paths according to the flight lengths. A computing system may be used to group the conductive paths according to grouping parameters 307. As an example of the grouping parameters 307, a computing system can derive subgroups within the set of paths 202 by grouping the paths having flight distances within a predetermined tolerance from each other. Also, the computing system can derive the subgroups based on a predetermined threshold and/or design rule, such as to maximize the number of traces within one subgrouping, minimize the difference in the number of traces across the subgroupings, or the like. Accordingly, the computing system can identify subgroupings of conductive paths that have flight lengths within threshold distances from each other.

At block 308, the method 300 can include computing routing parameters according to the flight lengths and corresponding groupings. The computing system can identify parameters including aspects or traits required for the communication of signal through the corresponding paths. For example, the computing system can identify signal traits 309, such as maximum speed (e.g., maximum oscillation), magnitude/voltage, conveyed current, slew rate requirement, and/or the like regarding the signals communicated over the corresponding paths. Also, the computing system can identify temporal relationships between the signals intended to be carried by the corresponding paths. For example, the computing system can identify the paths carrying the same signal intended to simultaneously arrive at the corresponding destinations. Also, the computing system can identify sequential relationship, such as for repeats, responses, confirmations or acknowledgements, or the like between signals. In some embodiments, the signal traits 309 can be provided to the computing system along with the circuit layout.

At block 310, the method 300 can include calculating path dimensions (e.g., the path dimension 214 of FIG. 2A). The computing system can calculate the path dimension 214 based on the flight distance 212. Accordingly, the set of paths 202 can have path dimensions that differ according to the corresponding flight distances 212. For example, different traces or lateral components within a redistribution layer can have different widths and/or thicknesses according to the end-to-end length of the trace between communicating components/endpoints. Also, vias and/or vertical connectors (e.g., pillars) can have different widths or diameters according to the corresponding flight distances 212.

In some embodiments, the computing system can calculate the path dimension 214 according to groupings. For example, each subset of paths grouped according to the grouping parameters 307 and/or the signal traits 309 can have the same path dimension. As an illustrative example, the computing system can compute a width applicable to the paths having flight distances that are within a threshold amount from each other. Moreover, the computing system can compute coordinate widths for signals having temporal relationships with each other, such as signals requiring simultaneous arrival/processing at the destinations.

The computing system can calculate the path dimensions 214 according to a predetermined routine, equation, model, and/or the like. For example, the computing system can follow the predetermined mechanism to simulate the intended communication signal according to the signal traits 309. Further, the computing system can calculate the resistance, the capacitance, the inductance, and/or other similar electrical effects associated with communicating the simulated signal across the paths for a given dimension (e.g., width). The computing system can adjust the dimensions of paths that have the temporal relationships and have different flight distances such that the simulated results satisfy the temporal requirements.

As an illustrative example, the computing system can identify paths carrying signals (e.g., broadcasted signals) that require arrival or processing at different/multiple locations to occur within a predetermined window. When such paths belong to different length-based groups, the computing system can adjust the widths of the paths, thereby changing the path resistance, capacitance, and/or inductance, such that the signals can arrive at the corresponding destinations within the prescribed window or a smaller window. In some embodiments, the computing system can assign the narrowest width (e.g., a predetermined value corresponding to manufacturing settings) to the path having the longest flight distance and then compute wider width for the next shorter sub-grouping of paths to match the rise and fall transition time to the longest path. Accordingly, the computing system can compute the widths for the sub-groupings of paths within the set of paths 202.

At block 312, the method 300 can include forming the conductive paths according to the calculated path dimensions. Forming the conductive paths can include manufacturing a structure, such as a wafer, a semiconductor die, a PCB, and/or the like, to include the set of paths 202 having varying path dimensions 214 that are based on the corresponding flight distances 212. In some embodiments, forming the conductive paths can correspond to providing the circuit layout and the calculated path dimensions to a separate manufacturer.

The resulting paths 202 that have path dimensions 214 adapted according to the flight distances 212 can leverage physical characteristics (e.g., resistance, capacitance, etc.) to meet the temporal requirements of the carried signals. Using the coordinated signals within the HBM/SoC as an example, the set of paths 202 with the length-dependent widths can provide an increase in the timing margin, such as between PHY and TSV.

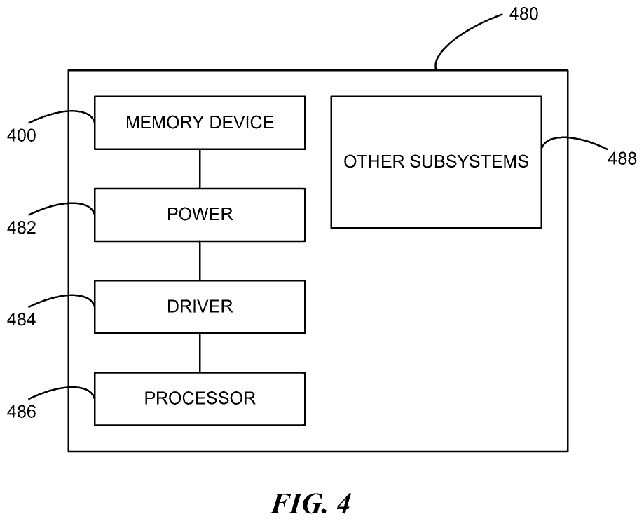

FIG. 4 is a schematic view of a system that includes an apparatus in accordance with embodiments of the present technology. Any one of the foregoing apparatuses (e.g., memory devices) described above with reference to FIGS. 1-3 can be incorporated into any of a myriad of larger and/or more complex systems, a representative example of which is system 480 shown schematically in FIG. 4. The system 480 can include a memory device 400, a power source 482, a driver 484, a processor 486, and/or other subsystems or components 488. The memory device 400 and/or any other device(s) illustrated in FIG. 4, can include features generally similar to those of the apparatus described above with reference to FIGS. 1-3, and can therefore include various features for performing a direct read request from a host device. The resulting system 480 can perform any of a wide variety of functions, such as memory storage, data processing, and/or other suitable functions. Accordingly, representative systems 480 can include, without limitation, hand-held devices (e.g., mobile phones, tablets, digital readers, and digital audio players), computers, vehicles, appliances and other products. Components of the system 480 may be housed in a single unit or distributed over multiple, interconnected units (e.g., through a communications network). The components of the system 480 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of DRAM devices. Apparatuses configured in accordance with other embodiments of the present technology, however, can include other types of suitable storage media in addition to or in lieu of DRAM devices, such as, devices incorporating NAND-based or NOR-based non-volatile storage media (e.g., NAND flash), magnetic storage media, phase-change storage media, ferroelectric storage media, etc.

The term “processing” as used herein includes manipulating signals and data, such as writing or programming, reading, erasing, refreshing, adjusting or changing values, calculating results, executing instructions, assembling, transferring, and/or manipulating data structures. The term data structure includes information arranged as bits, words or code-words, blocks, files, input data, system-generated data, such as calculated or generated data, and program data. Further, the term “dynamic” as used herein describes processes, functions, actions or implementation occurring during operation, usage or deployment of a corresponding device, system or embodiment, and after or while running manufacturer's or third-party firmware. The dynamically occurring processes, functions, actions or implementations can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to FIGS. 1-4.

I/We claim:

1. A semiconductor device, comprising:
a first endpoints;
a second endpoints;
a first signal path extending laterally and communicatively connecting the first endpoints,
wherein the first signal path includes an electrically conductive structure having (1) a first flight distance representative of a first signal traversing through the first signal path between the first endpoints and (2) a first path dimension measured along a direction orthogonal to a travel direction of the first signal; and
a second signal path extending laterally and communicatively connecting the second endpoints,
wherein the second signal path includes an electrically conductive structure having (1) a second flight distance representative of a second signal traversing through the second signal path between the second endpoints and (2) a first path dimension measured along a direction orthogonal to a travel direction of the first signal, and
wherein the second width is different from the first width according to a difference between the first flight distance and the second flight distance.

2. The semiconductor device of claim 1, wherein the first path dimension and the second path dimensions are widths for the first and second signal paths;
the semiconductor memory device is a high-bandwidth memory (HBM) device;
the first memory type is a Dynamic Random-Access Memory (DRAM); and
the interface manager includes circuitry configured to facilitate the self-test for the DRAM target memory cells in addition to the second memory type.

3. The semiconductor device of claim 1, wherein:
the semiconductor device is a memory device configured to form a chip stack with another device and includes (1) through silicon vias (TSVs) for routing the first and second signals along vertical directions and (2) physical layer (PHY) circuits for receiving and/or driving the first and second signals;
the first endpoints and the second endpoints include the TSVs and the PHY layer circuits; and
the first signal path and the second signal paths extend between the TSVs and the PHY layer circuits.

4. The semiconductor memory device of claim 1, further comprising:
a third signal path located relative to the first and second signal paths according to a pitch.

5. The semiconductor memory device of claim 4, wherein a first separation distance between the first and second signal paths is different from a second separation distance between the second and third signal paths.

6. A semiconductor device, comprising:
a first signal path extending between first endpoints, the first signal path configured to communicate a first signal between the first endpoints across a first flight distance,
wherein the first signal path includes an electrically conductive structure having a first path dimension that is based on the first flight distance,
wherein the first path dimension is measured along a direction orthogonal to a travel direction of the first signal; and
a second signal path extending between second endpoints, the second signal path configured to communicate a second signal between the second endpoints across a second flight distance,
wherein the second signal path includes an electrically conductive structure having a second path dimension that is based on the second flight distance and different from the first path dimension, and
wherein the second path dimension is measured along a direction orthogonal to a travel direction of the second signal.

7. The semiconductor device of claim 6, wherein at least a portion of the second signal path is parallel with a portion of the first signal path.

8. The semiconductor device of claim 6, wherein the first and second signal paths extend laterally.

9. The semiconductor device of claim 6, wherein the first and second path dimensions are widths.

10. The semiconductor device of claim 9, wherein:
the first flight distance is longer than the second flight distance; and
the second path dimension is wider than the first flight dimension based on having a shorter flight distance.

11. The semiconductor device of claim 6, further comprising:
a third signal path located relative to the first and second signal paths according to a pitch.

12. The semiconductor device of claim 11, wherein:
the first, second, and third signal paths comprise a set of paths; and
a longest path within the set of paths has a predetermined minimum width and a remainder of the set of paths have widths greater than the predetermined minimum width.

13. The semiconductor device of claim 11, wherein separation distances between paths within the set of paths are different based on different widths of the paths and in accordance with the pitch.

14. The semiconductor device of claim 6, wherein the first and second signal paths are configured to communicate the first and second signals that are temporally related to each other while communicating across the first and second flight distances that are different.

15. The semiconductor device of claim 14, wherein the first and second signals represent signals that are required to arrive at respective destinations within a predetermined time window.

16. A method of manufacturing a semiconductor device, the method comprising:
determining a circuit layout that identifies locations of a first signal path extending between first endpoints and a second signal path extending between second endpoints, wherein the first and second signal paths are electrically conductive structures configured for communicating first and second signals, respectively;
computing a first flight distance representative of a distance traversed by the first signal between the first endpoints and along the first signal path;
computing a second flight distance representative of a distance traversed by the second signal between the second endpoints and along the second signal path, wherein the second flight distance is different from the first flight distance;
calculating a first path dimension for the first signal path based on the first flight distance, wherein the first path dimension is measured along a direction orthogonal to a travel direction of the first signal;
calculating a second path dimension for the second signal path based on the second flight distance, wherein the second path dimension is measured along a direction orthogonal to a travel direction of the second signal and is different from the first path dimension; and
forming the first and second signal paths according to the circuit layout and the first and second path dimensions.

17. The method of claim 16, wherein:
the circuit layout identifies the first and second signal paths extending laterally along a plane; and
the first and second path dimensions are widths for the first and second signal paths.

18. The method of claim 16, wherein:
the circuit layout identifies a set of paths that includes the first and second signal paths;
the method further comprising:
identifying a longest path in the set of paths;
calculating a predetermined minimum dimension for the longest path; and
iteratively calculating dimensions for remaining paths in the set of paths,
wherein the dimensions for the remaining paths are greater than the predetermined minimum dimension, and
wherein iteratively calculating includes calculating the first path dimension and calculating the second path dimension.

19. The method of claim 18, wherein:
the set of paths are configured to communicate one or more signals that are temporally related to each other; and
iteratively calculating the dimensions for the remaining paths includes:
estimating a reference travel time for the longest path according to the predetermined minimum dimension; and
calculating the dimensions estimated to communicate corresponding signals along the remaining paths within a threshold window of the reference travel time.

20. The method of claim 19, further comprising:
sorting the set of paths according to according to corresponding flight distances;
identifying subgroupings within the set of paths according to signal flight distances, wherein paths within each subgroupings have the signal flight distances that are within a threshold range of each other;
wherein iteratively calculating the dimensions includes:
calculating a unique dimension for each subgrouping, wherein the paths within a subgrouping each have the unique dimension; and
successively increasing the dimensions in iterating across the subgroupings.
